(19) United States
(12) Patent Application Publication
(10) Pub. No.: US 2007/0230150 A1
(43) Pub. Date: Oct. 4, 2007

(54) POWER SUPPLY STRUCTURE FOR HIGH POWER CIRCUIT PACKAGES

(75) Inventors: Michele Castriotta, Ronco Briantino (IT); Stefano S Oggioni, Milano (IT); Mauro Spreafico, Sesto San Giovanni (IT); Giorgio Viero, Stezzano (IT)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 11/613,376

(22) Filed: Dec. 20, 2006

(30) Foreign Application Priority Data
Nov. 29, 2005 (EM) 05111426.2

(51) Int. Cl. H05K 1/11; H05K 1/14

(52) U.S. Cl. 361/794

(57) ABSTRACT

A power supply structure for high power circuit package is disclosed. According to the invention, the electrical connections between power planes are done through a plurality of coaxial structures that can be totally or partially implemented in the circuit shadow area of the electronic device carrier, for example under the engine area of the circuit. According to this principle, a same hole is used to transfer two different current levels, one on its periphery and the other one on its centre, doubling the electrical transfer capacity.

### FIELD OF THE INVENTION

The present invention relates generally to the structure and manufacture of electronic printed circuit boards and chip carriers and more specifically to a particular power supply structure for high power circuit packages.

### BACKGROUND OF THE INVENTION

An electronic device carrier comprises a thin plate formed of multiple layers onto which chips and other electronic components, such as capacitors, are mounted. Usually the half of layers of an electronic device carrier is dedicated to supply voltages planes. These supply voltages are supposed to be constant across the carrier and the chip, and are expected to operate reliably over the system's lifetime.

With the advent of ultra-deep submicron technology and the contemporaneous growth of modem system, the current flow across the electronic device carrier is increasing and so, it is generally required to use multiple current paths for providing the electronic device with required current from the board or arrangement on which the electronic device carrier is mounted. FIG. 1a illustrates a cross section view of an electronic device carrier 100 embedding such characteristic. For sake of illustration, the electronic device carrier 100 is based upon a stack of layers assigned to carry only power features and not signals, this is conventionally indicated using a sequence of “S” letters for signal devoted planes and “P” for power planes. A sequence such as SPPS (Signal Power Power Signal) can grow extensively becoming a very long one when referred to substrates with 10 or more layers, this is then shortened into a 2S2P that still stands for 2 signals planes and 2 power planes. In the cited prior art FIG. 1 shows a 0S2P core 105 and comprises two external power layers one on each side, no signal layers, that are covered with dielectric material (110-1, 110-2, and 110-3, 110-4, respectively). The core 105 comprises a plurality of Pin Through Holes, PTHs, or Resin Filled Plated trough hole, RFP (115-1 to 115-4) for transferring signals and/or power through the core 105. In the example of FIG. 1a, RFPs 115-1 and 115-3 are used to deliver a first current level and RFPs 115-2 and 115-4 are used to deliver a second current level, as illustrated with hatching. Conductive tracks are designed on each side of the core 105, and connected to the conductive tracks of the layers 110 through vias. In this example, the connection between the electronic device and the electronic device carrier is done through C4 bumps, generically referred to as 130, while the connection between the electronic device carrier and the board on which it is mounted is done through balls e.g., of the Ball Grid Array (BGA) type, generically referred to as 125. In particular, C4 bump 130-1 is connected to the conductive track 120-2 of the layer 110-2 that in turn, is connected to conductive track 120-1 of the layer 110-1. Conductive track 120-1 is connected to conductive track 120-3 through RFP 115-1. Conductive track 120-3 of the layer 110-3 is connected to conductive track 120-4 of the layer 110-4, on which ball 125-1 is soldered or glued. Typically, a power ball 125 of the BGA's type, based on the required current demand of the application, is capable to support up to four C4 bumps 130. FIG. 1b depicts a top view of the arrangement of the C4 bumps 130, RFPs 115, and balls 125.

Multiplying the number of PTHs or RFPs allows increasing the power supplied to the electronic device however, the number of PTHs and RFPs is limited by the pitch of the PTHs and RFPs i.e., the maximum number of PTHs and RFPs that can be done per length unit according to the manufacturing process. In the example given on FIG. 1, the PTHs/RFPs pitch, corresponding to the distance d1, is equal to 403.2 microns, 150 microns for the PTH/RFP drill diameter and 300 microns for the PTH/RFP pad diameter. The typical C4 bump pitch d2 is today 201.6 microns.

Historically the pitch of the silicon interconnection started from around 450 um and then progressively diminished to the present 200 um standard passing through intermediate distances such as 350, 300, 250, 225 um with visible trends to go further down to 175-150 um and below in the next years. The change of the silicon bumps was faster than the development capability of substrate manufacturer to keep a similar trend into the laminate manufacturing. The reason resides in having holes in the core still being mostly drilled by mechanical media. Smaller holes require equipment and tools with specific capabilities. While new technologies like laser drilling are being developed, their bigger challenge is still the need to create holes into composite materials, cladded with metal foils, posing great challenges in the laser power management, especially when dealing with so many different materials and their properties. Consequently to create holes into glass loaded dielectric and/or through metal layers that can be relatively thick (from 10 um up to 70 um for a 2 oz. Cu foil) the usage of different type of lasers require adjustments to be accommodated in terms of laser technology, materials, and many other aspects such as maximum number of processable layers, process step sequences and so on. Any change drives new validations and qualification expenses. Currently there is a technological gap between the capability of generating a great number of holes into the core, and the continuous trend in silicon interconnections density. The current strategy used by substrate manufacturer is to reduce the overall mechanical dimensions of the substrates, this is achieved by the application of smaller metal features paired with actions to reduce the overall thickness of the dielectric layers. A lower thickness allows handling expensive, but for some markets, still acceptable compromises between cost and manufacturing yield. Thin carriers with very small holes and high density of the same cannot be stacked during drilling process, this severely impact the overall manufacturing throughput. Thin cores allow to have small holes maintaining the aspect ratio (hole diameter/hole depth) within the capability of the plating process, plating is achieved with a continuous flow of plating solution into the holes, a too small holes affect the latter and plating is ineffective to withstand thermal stress or high currents.

Silicon technology, especially in high power and complex microprocessor and ASIC (Application Specific Integrated Circuit) design, is considerably growing the level of required currents for functionality, along the same path is the number of separate power domains required now by the multiple functions embedded into the silicon. A growing number of power domains with high currents demand (due to the low voltage) require controlling the DC drop of the power supply. The latter is controlled in growing the number of the interconnections into the substrate. Moreover the required number of power rails is also no longer very much compatible to the reduced thickness of substrates, ideally every single power domains should have at least a full power plane assigned to it. The growth of power planes jeopardize the aspect ratio for drilling small holes and consequently of the plating operations.

With the new trends in Microprocessors development now embracing the strategy of embedding multiple cores, referred to as engines in the document to avoid confusion with the core of the substrate, all the aforementioned requirements are amplified by the quantity of each embedded engine into the same device with the need to be all accomplished simultaneously.

As a consequence, there is a need for a power supply structure allowing high power to be transmitted through the core of an electronic device carrier and for a multi-channel power supply structure allowing current distribution through the core of an electronic device carrier.

### SUMMARY OF THE INVENTION

Thus, it is a broad object of the invention to remedy the shortcomings of the prior art as described here above.

It is another object of the invention to provide a power supply architecture for high power circuit package reducing the package surface dedicated to power supply paths.

It is a further object of the invention to provide a power supply architecture for high power circuit package adapted to reduce resistance and inductance parasitic effects.

It is a further object of the invention to provide a multi-channel power supply architecture for power circuit package reducing the package surface dedicated to power supply paths.

It is still a further object of the invention to provide a power supply architecture for high power circuit package reducing the package surface dedicated to power supply paths, adapted to reduce resistance and inductance parasitic effects, based upon standard manufacturing processes.

The accomplishment of these and other related objects is achieved by a power supply structure in an electronic device carrier adapted to connect a first conductive track of a first conductive layer to a second conductive track of a second conductive layer and a third conductive track of said first conductive layer to a fourth conductive track of said second conductive layer, a dielectric layer being disposed between said first and second conductive layers, said power supply structure comprising a plurality of coaxial structure, said coaxial structure comprising:
a first conductive path connecting said first and second conductive tracks;
a second conductive path, surrounding said first conductive path, connecting said third and fourth conductive tracks, said first and second conductive path having a common axis, approximately perpendicular to said conductive layers; and,
a dielectric material disposed between said first and second conductive path;
   and by a method for manufacturing a power supply structure as described above, said method comprising the steps of:
drilling first holes in the electronic device carrier;
plating said first holes;
filling said plated holes with a dielectric material;
drilling second holes in said filled plated holes such that said first and second holes share a common axis and the diameter of said second holes is less than the one of said first holes; and,
plating said second hole.

Further embodiments of the invention are provided in the appended dependent claims.

Further advantages of the present invention will become apparent to the ones skilled in the art upon examination of the drawings and detailed description. It is intended that any additional advantages be incorporated herein.

### BRIEF DESCRIPTION OF THE DRAWINGS

FIG. 1, comprising FIG. 1a and FIG. 1b, illustrates a typical power structure of an electronic device carrier according to the prior art.

FIG. 2, comprising FIG. 2a and FIG. 2b, illustrates an example of the coaxial via structures according to the invention.

FIG. 3, comprising FIGS. 3a and 3b, depict a first embodiment for positioning connection pads on the surface of the electronic device carrier.

FIG. 4, comprising FIGS. 3a, 4b, and 4c, shows a second embodiment for positioning connection pads on the surface of the electronic device carrier.

### DETAILED DESCRIPTION OF THE PREFERRED EMBODIMENT

The power structure for high power circuit package according to the invention is base upon the use of coaxial power structures that can be totally or partially implemented in the circuit shadow area of the electronic device carrier, for example under the engine area of the circuit. According to this principle, a same hole is used to transfer two different current levels, one on its periphery and the other one on its centre.

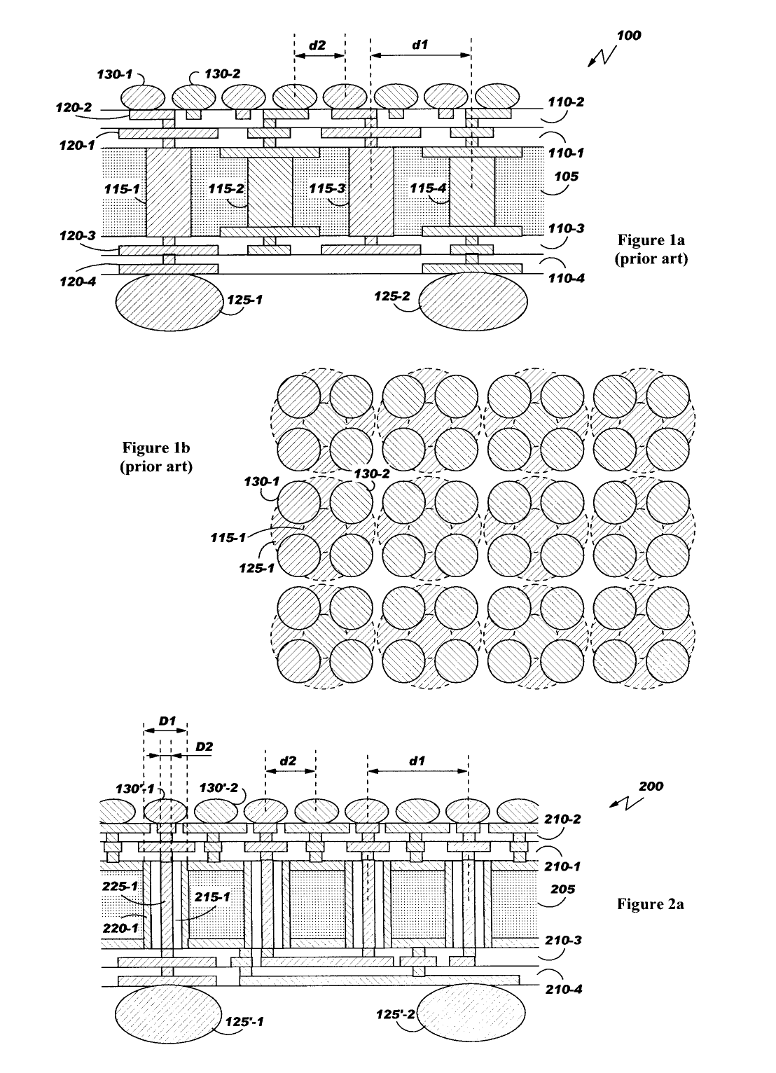

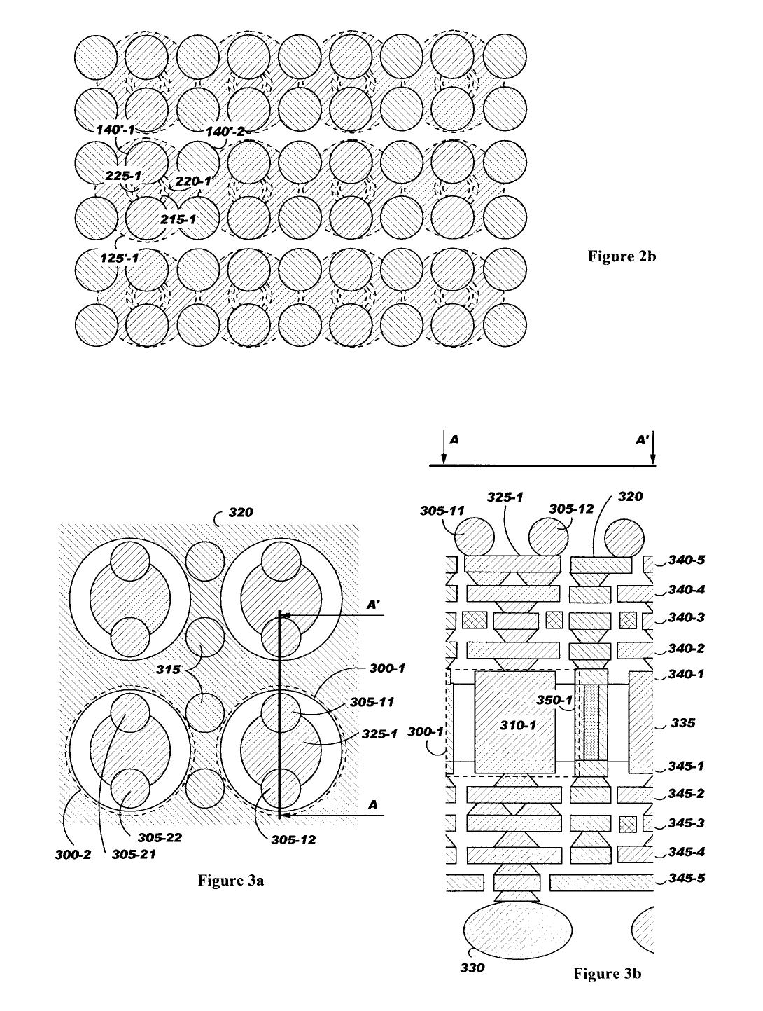

FIG. 2a illustrates a cross section view of an electronic device carrier 200. Like the electronic device carrier 100, the electronic device carrier 200 is based upon an 0S2P core 205 and comprises two power external layers on each side, no signal layers, that are covered with dielectric material (210-1, 210-2, and 210-3, 210-4, respectively). The core 205 comprises a plurality of first holes having a diameter D1, generically referred to as 215, that are plated with conductive material to form a conductive cylinder, generically referred to as 220. After being plated, the holes are filled with dielectric material such as resin, forming a standard RFP. The dielectric material is then drilled (mechanical drilling or chemical drilling such as laser drilling) to form second holes, sharing the same axis as the first holes, having a diameter D2 with D2<D1, generically referred to as 225. The second holes are filled with conductive material. A pair of plated first hole and filled second hole forms a coaxial structure that is used to carry two different current levels. The coaxial structure replaces the traditional PTH via, used to deliver current into the electronic device carrier, for increasing the number of power connection per surface unit.

The pitch between coaxial structure is determined by the manufacturing process and so, it is the same as the one used in the prior art to manufacture close PTHs or RFPs. Accordingly, the coaxial structure of the invention allows to increase the density of 100% of vertical paths compared to traditional technology.

FIG. 2b depicts a top view of the arrangement of the C4 bumps 130′, coaxial structures, and balls 125′. In the example given on FIG. 2, the pitch of the coaxial structure, corresponding to the distance d1, is equal to 403.2 microns, 350 microns for the external RFP drill diameter, 450 microns for the RFP land into power plane, and 80 microns for the coaxial via drill diameter. Compared with the system shown on FIG. 1, the number of current vertical path is doubled.

The power coaxial structure can be accomplished through a sequence of operations already used in the standard manufacturing process. For example, the power coaxial structure may be formed by first drilling with a mechanical drill bit the larger diameter hole with diameter D1, plating the drill hole, filling the plated hole with a dielectric material, e.g. epoxy resin, polyphenylene (PPE), annylated polyphenylene ether (APPE), benzocyclobutene (BCB), cyanate (triazine) resin, polytetrafluorethylene (PTFE), bismaleimide triazine (BT) resin, polyimide, polyester, phenolic or poly(phenyleneetherketone) (PEEK), drilling by the same or another method such as laser using excime laser, CO2 laser or Nd-YAG (neomodium-yttrium alluminium garnet) infrared laser, a new pass through second hole with diameter D2 in the substantial center of the larger plated hole filled with dielectric material, and finally filling the second hole, for example by plating the second hole with an electroless copper process or with a conductive material.

Different arrangements can be used to interconnect C4 bumps and BGA's type of balls to the power coaxial structure. According to a preferred embodiment, the C4 bumps are aligned according to lines and columns wherein each two columns is dedicated to C4 bumps connected to the first current level e.g., VDD, and the others are dedicated to C4 bumps connected to the second current level e.g., ground.

FIG. 3 illustrates a first embodiment wherein two C4 bumps are positioned at the periphery of the cylinder formed by each central conductive path of the coaxial structures, these two C4 bumps being connected to this central conductive path of the coaxial structure. FIG. 3a represents a top view of the electronic device carrier and FIG. 3b depicts a partial section view of the electronic device carrier along A-A′ axis. As shown, the two C4 bumps 305-11 and 305-12 are positioned at the periphery of the cylinder formed by the central part 310-1 of the coaxial structure 300-1. Likewise, the two C4 bumps 305-21 and 305-22 are positioned at the periphery of the cylinder formed by the central part of the coaxial structure 300-2. As depicted with hatching, the C4 bumps 305 are connected to the central part 310 of the coaxial structures 300 and so, share the same current level e.g., VDD. The C4 bumps 315 belonging to the columns positioned between the columns of C4 bumps 305 connected to the external conductive path 350-1 of the coaxial structures are connected to the conductive track 320, designed on the surface of the electronic device carrier, corresponding to the second current level e.g., ground. C4 bumps 305 are soldered or glued to conductive tracks 325, designed on the surface of the electronic device carrier. The electrical connections between the conductive tracks 320 and 325 to the coaxial structure is done through the layers of the electronic device carrier according to standard designed rules as shown on FIG. 3b.

For sake of illustration, each side of the core 335 of the electronic device carrier represented on FIG. 3 comprises five conductive layers insulated one to the others with dielectric material such as epoxy. The surfaces of the electronic device carrier are also protected with dielectric material. In this example, the layers 340-1 and 345-1, generally referred to as FC1 and BC1, and the layers 340-5 and 345-5, generally referred to as FC5 and BC5, represent firsts and fourths power planes, respectively, corresponding to the second current level e.g., ground. FC and BC are conventional names to identify Surface Laminar Circuit (SLC) build up layers. All the build up layers on the top side of the core are identified with FCx nomenclature, where FC means Front Circuit and x is the number of the layer. Likewise, all the build up layer on the bottom side of the core are identified with BCx nomenclature, where BC means Back Circuit and x is the number of the layer. The shape of the conductive path designed on layers 340-1, 345-1, and 340-5 is preferably similar to the one referred to as 320 on FIG. 3a. The layers 340-2 and 345-2, generally referred to as FC2 and BC2, and the layers 340-4 and 345-4, generally referred to as FC4 and BC4, represent seconds and thirds power planes, respectively, corresponding to the first current level e.g., VDD. The layers 340-3 and 345-3, generally referred to as FC3 and BC3, represent signal layers wherein signal paths are designed. It is to be noticed that in addition to transfer current, the power planes shield the signal paths from electromagnetic perturbations.

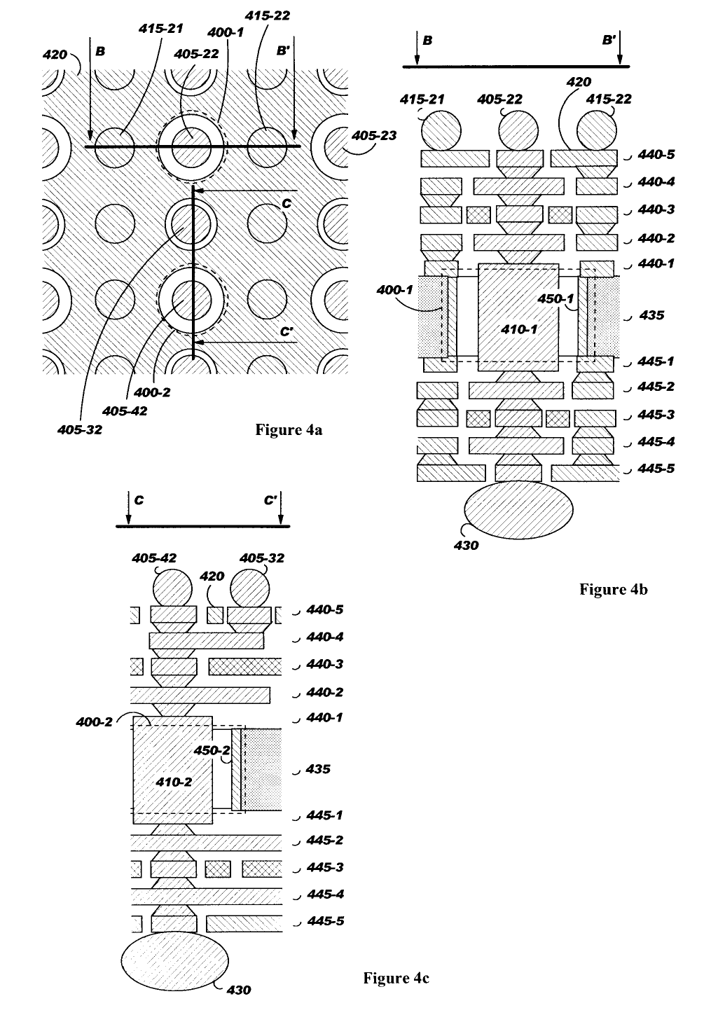

FIG. 4 illustrates a second embodiment where one C4 bump is aligned on each central part of the coaxial structure. Similarly to FIG. 3, FIG. 4 comprises FIG. 4a that represents a top view of the electronic device carrier and FIGS. 4b and 4c that depict partial section views of the same electronic device carrier along B-B′ and C-C′ axis.

As shown, one C4 bump is aligned on the axis of each coaxial structure and one C4 bump is positioned approximately in the middle of two C4 bumps aligned on the axis of two adjacent coaxial structures. For example, C4 bump 405-22 is aligned on the axis of the coaxial structure 400-1, C4 bump 405-42 is aligned on the axis of the coaxial structure 400-2, and C4 bumps 405-32 and 415-22 are positioned between C4 bumps 405-22 and 405-42, and C4 bumps 405-22 and 405-23, respectively. The C4 bumps aligned on the axis of the coaxial structure are connected to the central part 410 of the coaxial structure, preferably according to a vertical path as shown on FIGS. 4b and 4c. The C4 bumps aligned on the axis of the coaxial structure and the other C4 bumps belonging to the same columns correspond to a first current level e.g., VDD. The C4 bumps of the other columns correspond to the second current level e.g., ground, and they are connected to the external conductive path 450 of the coaxial structure.

The layer structure for connecting BGA's type of balls 430 to C4 bumps and for transmitting signals is similar to the one described by reference to FIG. 3. Each side of the core 435 of the electronic device carrier comprises five conductive layers insulated one to the others with dielectric material such as epoxy, the surfaces of the electronic device carrier being also protected with dielectric material. In this example, the layers FC1 (340-1) and BC1 (345-1), and the layers FC5 (340-5) and BC5 (345-5), represent firsts and fourths power planes, respectively, corresponding to the second current level e.g., ground. The layers FC2 (340-2) and BC2 (345-2), and the layers FC4 (340-4) and BC4 (345-4), represent seconds and thirds power planes, respectively, corresponding to the first current level e.g., VDD. The layers FC3 (340-3) and BC3 (345-3), represent signal layers wherein signal paths are designed.

The arrangement according to FIG. 4 has a direct vertical connection between C4 bumps and the central part of the coaxial structures, with short electrical paths. This is a space saving solution for the underneath layers. It can be used for low Inductance requirements. However, the vertical structure, surrounded by a resin matrix, shows stiffness behavior that can lead to a front of thermal and mechanical stress.

The arrangement according to FIG. 3 is more flexible and easy to manufacture. It shows that stacked microvias placed on the center of coaxial structure are not necessary since the interconnection between different layers can be done with jogs. In such case a more relaxed microvias arrangement is available.

The two solutions shows the flexibility of the invention, they are not mutually exclusive and they can be used together in the same application. It should be noticed that in both cases, the power coaxial structure density does not change.

Multiple engines mP are requiring high level of currents in the order of 100 to 200 A being fed in and out through the component carrier. The level of complexity of the actual Semiconductor device configurations require that currents need to be delivered right into the specific regions of the device. For functional reasons there is no possibility to distribute power within the silicon to the different macros and functional areas. To accomplish this “regionalized power distribution” developers are using the solution of increasing the quantities of power connections per unit of surface, through a disposition of the contacts across the whole area of the device. The above drives the continues challenge in reducing the pitch (distance) between the rows and columns of these semiconductor bumps (connections). Pitch reductions is also affecting the dimensions of these connections, that are decreasing in size accordingly to their manufacturing process capability to build them reliably, and keeping them separated from each others, to a minimum isolation. Reduction of their size drives to some extend a limitation in the maximum current (reduction of the equivalent conductor cross sectional area) they can reliably carry for the expected life of the product. While this can be achieved using photolitographic and wet processes or through some deposition process at silicon level an analogous design approach for similar densities is needed to be available at carrier level (organic laminates). This is partially achieved using the recently developed build up substrates where the outer layers of the stacks are generated using layers of resins, with no fiberglass reinforcements, added sequentially to a center rigid core (resin loaded reinforced glass cloth cladded with copper foils). These added layers can be plated and processed quite easily with laser technology that allows to create dense matrixes of connections between the layers in a compatible density to the semiconductor connections. A current available density with 200 um pitch is using 60 um diameter laser drilled hole into a supporting pad of 120 um, this still allow an isolation between the pads of 80 um.

While the added layers of the organic laminate carrier can offer a possible path to a compatible density of power connection density, the limiting factor is the central piece of the substrate construction. The central portion of the laminate stack-up represent the only portion that has a rigid portion that is the greatest contributor to the package robustness. Microprocessor packages, due to their high level of power dissipation, require aggressive and advanced cooling solutions that drive the clamping of these electronic packages between plates or sockets that than are then mated to heatsinks through some advance thermal materials. These materials are very much effective to conduct heat as much their overall thickness is kept low, which is done through pressure with values that can reach several hundreds Nf/cm2

The rigid portion of the laminate need to be thick enough to support those loads without yielding to pressure (at temperature as well as room temperature), it is the same central section that hosts the thick Cu (low DC resistance) power planes. Power planes can use metal layers of different thicknesses from 9 up to 70 um and even greater thicknesses. These central sections can be drilled through mechanical drill bits, and the thicker they become (due to the layer stacking) the more challenging they are. Minimal diameter using industrial capability, at volume production, are in the 150 um diameter ranges, with very few producers moving to 100 um drill bits diameter that can be used on quite thin central cores, in the range of 400 um and below, total thickness and no metal layers inside. Outer metal layers of the central sections are devoted to power, they also host all the connections that move from one side of the substrate to the opposite one, the required steps for plating these holes usually adds further thickness to the Copper present on these outer layers enlarging the dimension of the minimum gap possible between metal features.

A 150 um hole requires, in an aggressive design for manufacturing environment, a hosting pad of 250 um diameter. Thick copper drives to have relative large gaps between the metal features sitting on the same plane, that drives the 250 um diameter lands being placed to a minimum distance of at least 75 um to the closest neighbor. That results in being much larger than the minimum pitch available on the silicon with the resulting pitch is 325 um to be compared against the 200 um of the semiconductor. A more standard design would call at least for a 100 gap translating the minimum pitch at a 400 um, the double of the device connection.

An adversing factor to the above design strategy is the need to assign full power planes to each power domain required into a microprocessor. Things gets to a greater order of magnitude when there are Multi-Chip Module (MCM) being considered with multiple microprocessor being considered. The ever growing challenge of accommodating more and more different power domains in the package feeding the new mP are creating the need to growth the number of power planes required into the overall layers stack. A greater number of power planes translates into a thicker core, that consequently requires larger drill bits to drill through making the spatial correlation between the silicon device connection density to the laminate density worse and worse.

As an example a core thickness of 800 um with a cross section of 4 metal layers drives a drill pitch of 600 um with holes of 250 um, silicon devices are still on 200 um pitch.

In a multi-engines device the density of current feeding is such that the module connections available in the area correlated to the projection of the device shadow are not sufficient to guarantee the power demand. Once this ideal line is crossed the only vertical feeding paths, theoretically available from the module/PCB connections across the substrate to the semiconductor device connections, are no longer sufficient to supply the current demand, there is then the need to include low resistance electrical paths capable to contribute to an equal level of the vertical paths, to supply power to the chip. These added path use horizontal current path provided by the power planes embedded into the substrate cores.

High density and redundant power feeding structures are required to lower the overall electrical resistance and to minimize other critical effects need to be accounted such as self heating of the substrate due to Joule effect as well as electromigration phenomena enhanced by current crowding effects.

All different power domains used in multi-engines mP are feeding currents to one or more silicon devices, all the currents have generally a common return path through the ground network. In a very dense power connections area with multi-power domains all of them are contributing in loading the return current GND path. This translates in requiring a greater redundancy of GND connection compared to the single requirements of a single power domain. This is true due to the cumulative effect that some GND structures may see to contributing neighboring different power structures. The above may translates in the requirement to avoid “Hot spots” (current crowding) in the return power path increasing the equivalent cross section of the GND conductors compared to the single contributors of the different powers.

Mechanically drilled holes are then plated with copper fully filled with a polymer resin that is then cured. This cured resin is a processable channel with a laser to open a new vertical path that is then metallized. The resin vertical channel is already being freed by the previous mechanical drilling of glass fibers and metal layers, so the very the effective and known technique using laser technology already developed in the processing of the build up layers can be used.

For the above reason placing the GND on the outer holes with a larger diameter compared to the smaller nested holes is equivalent to an increase of its conductor cross section, due to the fact that a larger diameter translates in a larger conductor cross section.

Even the usage of relaxed rules in terms of drilling mechanical holes but with the possibility of placing another holes into the first hole is delivering the possibility to concentrate a great number of holes per unit of surface feeding the different power domains and controlling the possibility of current crowding in the GND return path. An effective 450 um larger holes pitch once containing other vertical paths become an equivalent matrix of 225 um pitch identical holes (same equivalent conductor cross section) but without the risk of unbalanced return currents load due to proximity of the same GND vertical structure to multiple power domains vertical feeding structures.

These concentration of power structures can be accommodate under the different mP engines providing effective low resistance paths to the feeding and return currents, these can also be accommodate within regular structures in combination to achieve similar distribution according to their relative positions (cumulative electrical path resistive value) to achieve a common distribution of power intermixing the different structures to achieve a current partition (partitor) with equal values of current but different “power feeding” structures.

The latter embodiment becomes evident in the case of substrates carrying more than one semiconductor device, where the substrate is generally designed to have signals being assigned along the periphery of the module pin-out to ease the design of the hosting printed circuit boards. The resulting pin out partitioning leaves the contacts into the central area to be used for power feeding. With such embodiment the hosted semiconductors cannot be all placed just above the power feeding structures. The resulting placement of the semiconductors on the substrates usually allows a partial overlap with these substrate power structures, that can be coaxially made to maximise their beneficial effects while other power domains can be routed inside a multilayer substrate core reaching to the required silicon structures either using coaxial or not coaxial structures as referred above.

Naturally, in order to satisfy local and specific requirements, a person skilled in the art may apply to the solution described above many modifications and alterations all of which, however, are included within the scope of protection of the invention as defined by the following claims.

1. A power supply structure in an electronic device carrier adapted to connect a first conductive track of a first conductive layer to a second conductive track of a second conductive layer and a third conductive track of said first conductive layer to a fourth conductive track of said second conductive layer, a dielectric layer being disposed between said first and second conductive layers, said power supply structure comprising a plurality of coaxial structure, said coaxial structure comprising:
a first conductive path connecting said first and second conductive tracks;
a second conductive path, surrounding said first conductive path, connecting said third and fourth conductive tracks, said first and second conductive path having a common axis, approximately perpendicular to said conductive layers; and
a dielectric material disposed between said first and second conductive path.

2. The power supply structure of claim 1 wherein the distance between adjacent coaxial structure is approximately equal to the minimum distance allowed by the manufacturing process between two adjacent plated through holes.

3. The power supply structure of claim 1 wherein the distance between two adjacent coaxial structures is approximately equal to the double distance allowed by the manufacturing process between two adjacent semiconductor bumps.

4. The power supply structure of claim 1 wherein the core of said electronic device carrier is disposed between said first and second conductive layers.

5. The power supply structure of claim 1 further comprising a third conductive layer wherein said third conductive track is designed.

6. The power supply structure of claim 5 further comprising a fourth conductive layer wherein said fourth conductive track is designed.

7. The power supply structure of claim 1 further comprising on the external surface at least as many pads as coaxial structures, at least one of said pads being aligned on the axis of said coaxial structure.

8. The power supply structure of claim 1 further comprising on the external surface at least as many pads as coaxial structures, at least one of said pads being aligned on the cylinder formed by said first conductive path.

9. An electronic device carrier comprising first and second power supply structures, said first and second power supply structures having a plurality of coaxial structure, said coaxial structure comprising:
a first conductive path connecting said first and second conductive tracks;
a second conductive path, surrounding said first conductive path, connecting said third and fourth conductive tracks, said first and second conductive path having a common axis, approximately perpendicular to said conductive layers; and
a dielectric material disposed between said first and second conductive path;
wherein said first and second power supply structure are assigned to at least two different power domains.
